(19) United States
(12) Patent Application Publication
(10) Pub. No.: US 2025/0299768 A1
(43) Pub. Date: Sep. 25, 2025

(54) DATA STORAGE DEVICE AND OPERATION METHOD THEREOF

(71) Applicant: SK hynix Inc., Gyeonggi-do (KR)

(72) Inventor: Se Joong KIM, Gyeonggi-do (KR)

(21) Appl. No.: 18/939,521

(22) Filed: Nov. 7, 2024

(30) Foreign Application Priority Data
Mar. 25, 2024 (KR) 10-2024-0040317

(51) Int. Cl. G11C 29/00; G11C 29/52

(52) U.S. Cl. CPC G11C 29/76; G11C 29/52; G11C 29/808

(57) ABSTRACT

Embodiments of the present disclosure relate to a data storage device that manages a spare region in each memory area to be maintained at a predetermined ratio or size or higher based on defect information of each memory area, and an operation method of the data storage device. According to the embodiments of the present disclosure, there may be provided an operation method of a data storage device, the method comprising classifying a plurality of memory areas provided in a memory device into a plurality of storage areas, managing the plurality of storage areas by mapping a logical address externally received to each of the plurality of storage areas, monitoring defect information generated in a memory area corresponding to each of the plurality of storage areas, and remapping the logical addresses for each of the plurality of storage areas based on the defect information.

### CROSS REFERENCE TO RELATED APPLICATION

The present application claims the benefit 35 U.S.C. § 119(a) of Korea Patent Application No. 10-2024-0040317, filed Mar. 25, 2024, the content of which is incorporated herein for all purposes by reference in its entirety.

### BACKGROUND

### Field

Embodiments of the present disclosure relate to a data storage device and a method thereof, and more specifically, to a data storage device and an operation method of the data storage device, which can manage a spare region in each memory area to be maintained at a predetermined ratio or size, or higher based on defect information of each memory area.

### Description of the Related Art

A data storage device is a device that can store data based on a request (or a command) of a host, such as a computer, a mobile terminal such as a smartphone, a tablet, or various electronic devices.

The data storage device may further include a controller for controlling memory (e.g., volatile memory/non-volatile memory), and the controller may receive commands from the host, and execute or control operations for reading, writing, or erasing data in a memory device included in the data storage device based on the received command.

The data storage device may include a spare data storage area of a predetermined ratio in order to continuously operate even when some memory cells are defective. The spare data storage area may store data in place of the defective memory cells. However, as the number of defective memory cells increases, the ratio of the spare storage region gradually decreases, and when it falls below a predetermined ratio, the data storage device may not be used any longer.

In particular, when the data storage device has a plurality of physically or logically separated memory areas, the ratio of the spare storage region of each memory area is independently calculated, and when any of the memory areas falls below a predetermined ratio, the data storage device is determined not to be used any longer although the other memory areas can be used.

### SUMMARY

Embodiments of the present disclosure may provide a data storage device and an operation method of the data storage device, which can manage the ratio of a spare storage region of each memory area to be equal to or higher than a predetermined size or ratio in order to improve the inefficiency described above.

An embodiment of the present disclosure may provide a data storage device and an operation method of the data storage device, which can manage the ratio of a spare storage region of each memory area to be equal to or higher than a predetermined size or ratio by adjusting the number of logical addresses mapped to each memory area based on a bad block count value of bad blocks generated in each of a plurality of memory areas.

The technical problems to be solved in this disclosure are not limited to the technical problems mentioned above, and unmentioned other technical problems may be clearly understood by those skilled in the art from the following description.

In an embodiment of the present disclosure, there is provided a data storage device comprising a memory device including a plurality of memory areas and a controller configured to classify the plurality of memory areas as a plurality of storage areas, manage the plurality of storage areas by mapping a logical address externally received to each of the plurality of storage areas, monitor defect information generated in a memory area corresponding to each of the plurality of storage areas, and remap the logical addresses for each of the plurality of storage areas based on the defect information.

In the embodiment of the present disclosure, the controller comprises a host interface layer (HIL) and a plurality of flash translation layers (FTLs), and is configured to separately manage each of the plurality of storage areas through the plurality of FTLs, each of the plurality of FTLs is configured to process a command externally received for a corresponding storage area, and count the bad blocks generated in the corresponding storage area and the HIL is configured to map and remap the logical addresses to each of the plurality of storage areas, and transmit the command to one of the plurality of FTLs based on the mapped logical addresses.

In other embodiments of the present disclosure an operation method of a data storage device is provided, the method comprising classifying a plurality of memory areas provided in a memory device into a plurality of storage areas, managing the plurality of storage areas by mapping a logical address externally received to each of the plurality of storage areas, monitoring defect information generated in a memory area corresponding to each of the plurality of storage areas and remapping the logical addresses for each of the plurality of storage areas based on the defect information.

### BRIEF DESCRIPTION OF THE DRAWINGS

FIG. 1 is a schematic configuration diagram of a data storage device according to an embodiment of the present disclosure.

FIG. 2 is a flowchart illustrating an operation method of a data storage device according to an embodiment of the present disclosure.

FIG. 3 is a block diagram for describing a controller according to an embodiment of the present disclosure.

FIG. 4 is a flowchart for managing bad blocks by a controller according to an embodiment of the present disclosure.

FIG. 5 is a flowchart illustrating in detail an operation S330 shown in FIG. 4.

FIG. 6 is a flowchart illustrating in detail an operation S410 shown in FIG. 5.

FIGS. 7 to 9 are views for describing operations of the controller shown in FIGS. 5 and 6 according to various embodiments of the present disclosure.

### DETAILED DESCRIPTION

Hereinafter, embodiments of the present disclosure will be described in detail with reference to the accompanying drawings.

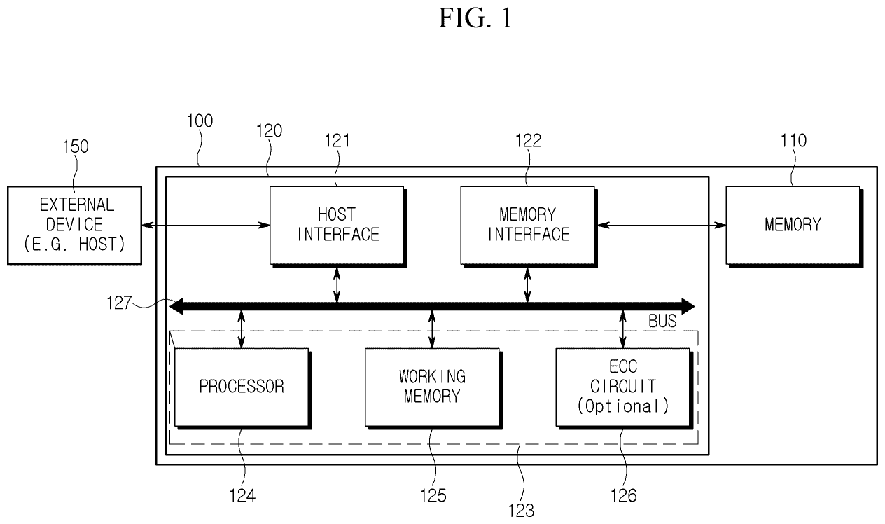

FIG. 1 is a schematic configuration diagram of a data storage device 100 according to an embodiment of the present disclosure.

Referring to FIG. 1, the data storage device 100 may include a memory device 110 that stores data, a controller 120 that controls the memory device 110, and the like.

The memory device 110 operates in response to control of the controller 120. Here, the operation of the memory device 110 may include, for example, a read operation, a program operation (also referred to as a write operation), an erase operation, and the like.

For example, the memory device 110 may be implemented in various types, such as a double data rate synchronous dynamic random-access memory (DDR SDRAM), a low power double data rate4 (LPDDR4) SDRAM, a graphics double data rate (GDDR) SDRAM, a low power DDR (LPDDR), a RAMBUS dynamic random-access memory (RDRAM), a 3D NAND flash memory, a NOR flash memory, a resistive random access memory (RRAM), a phase-change memory (PRAM), a magneto resistive random access memory (MRAM), a Ferroelectric random access memory (FRAM)), a spin transfer torque random access memory (STT-RAM), and the like.

The memory device 110 may be implemented as a three-dimensional array structure. The embodiments of the present disclosure may also be applied to charge trap flash (CTF) in which a charge storage layer is configured as an insulating film, as well as a flash memory in which the charge storage layer is configured as a conductive floating gate.

The memory device 110 may receive a command, an address, and the like from the controller 120, and access an area selected by the address among the memory cell array. That is, the memory device 110 may perform an operation directed by the command on the area selected by the address.

For example, the memory device 110 may perform the program operation, read operation, erase operation, and the like. In relation thereto, when performing the program operation, the memory device 110 may program data in an area selected by the address. When performing the read operation, the memory device 110 may read data from an area selected by the address. When performing the erase operation, the memory device 110 may erase data stored in an area selected by the address.

The controller 120 may control the write (program), read, erase, and background operations on the memory device 110. Here, the background operation may be, for example, garbage collection (GC), wear leveling (WL), read reclaim (RR), bad block management (BBM) operation, hyper write migration, and SLC through migration, or the like, and the embodiments are not limited thereto.

The controller 120 may control the operation of the memory device 110 in response to a request from an external device (e.g., HOST) 150 located outside the data storage device 100. On the other hand, the controller 120 may also control the operation of the memory device 110 independently from the request of the external device 150.

The external device 150 may be an ultra-mobile PC (UMPC), a workstation, a personal digital assistant (PDA), a tablet, a mobile phone, a smart phone, an e-book, a portable multimedia player (PMP), a portable game console, a navigation device, a black box, a digital camera, a digital multimedia broadcasting (DMB) player, a smart television, a digital audio recorder, a digital audio player, a digital picture recorder, a digital picture player, a digital video recorder, a digital video player, a storage constituting a data center, one of various electronic devices constituting a home network, one of various electronic devices constituting a computer network, one of various electronic devices constituting a telematics network, a radio frequency identification (RFID) device, a mobile device that drives on the ground, in the water, or in the air under human control or autonomously (e.g., a vehicle, a robot, or a drone), or the like.

The external device 150 may include at least one operating system (OS). The operating system may generally manage and control the functions and operations of the external device and provide interactive operations between the external device and the data storage device 100. The operating system may be classified into a general operating system and a mobile operating system according to mobility of the external device.

The controller 120 and the external device 150 may be devices separated from each other. In some cases, the controller 120 and the external device 150 may be implemented to be integrated as one device. It will be described below, for example, that the controller 120 and the external device 150 are devices separated from each other for convenience of description.

Referring to FIG. 1, the controller 120 may include a memory interface 122, a control circuit 123, and the like, and may further include a host interface 121 or the like.

The host interface 121 provides an interface for communicating with the external device 150. For example, the host interface 121 provides an interface that uses at least one of various communication interfaces or protocols, such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, and an integrated drive electronics (IDE) protocol, a proprietary protocol, and the like.

When receiving a command from an external device, the control circuit 123 may receive the command through the host interface 121 and perform an operation that processes the received command.

The memory interface 122 may be connected to the memory device 110 and provide an interface for communicating with the memory device 110. That is, the memory interface 122 may provide an interface between the memory device 110 and the controller 120 in response to control of the control circuit 123.

The control circuit 123 controls the operation of the memory device 110 by performing the overall control operation of the controller 120. To this end, for example, the control circuit 123 may include one or more among a processor 124, a working memory 125, and the like, and may optionally include an error detection and correction circuit (ECC circuit) 126, and the like.

The processor 124 may control the overall operation of the controller 120 and perform logical operations. The processor 124 may communicate with the external device through the host interface 121 and communicate with the memory device 110 through the memory interface 122.

The processor 124 may perform the function of a flash translation layer (FTL). The processor 124 may convert a logical block address (LBA) provided by the host into a physical block address (PBA) through the flash translation layer (FTL). The flash translation layer (FTL) may receive a logical block address (LBA) as an input and convert it into a physical block address (PBA) using a mapping table.

The flash conversion layer has several address mapping methods according to the mapping unit. Representative address mapping methods include a page mapping method, a block mapping method, and a hybrid mapping method.

The processor 124 may randomize data received from the external device. For example, the processor 124 may randomize data received from the external device using a set randomizing seed. The randomized data may be provided to the memory device 110 to be programmed in the memory cell array of the memory 100.

The processor 124 may derandomize the data received from the memory device 110 when performing a read operation. For example, the processor 124 may derandomize the data received from the memory device 110 using a derandomizing seed. The derandomized data may be output to the external device.

According to an embodiment, the processor 124 is an application specific integrated circuit (ASIC) in which the functions described above are implemented in the form of logic, and may control the operation of the controller 120 based on the functions implemented in hardware.

According to another embodiment, the processor 124 is a general-purpose processor or a digital signaling processor (DSP), and may control the operation of the controller 120 by loading and executing firmware. The processor 124 may execute (drive) the firmware loaded on the working memory 125 at the time of booting in order to control the overall operation of the controller 120 and perform logical operations.

For example, the firmware may include a flash translation layer (FTL) for performing a conversion function between a logical address that allows an external device to recognize the data storage device 100 and a physical address of the memory device 110 in the data storage device 100, a host interface layer (HIL) for interpreting a command transmitted from the external device 150 to the data storage device 100 and transmitting the command to the flash translation layer (FTL), a flash interface layer (FIL) for transmitting a command indicated by the flash translation layer (FTL) to the memory device 110, and the like.

For example, such firmware may be loaded on the working memory 125 from the memory device 110 or a separate non-volatile memory (e.g., ROM, or flash) located outside the memory device 110. When executing the booting operation after power-on, the processor 124 may first load all or part of the firmware onto the working memory 125.

The processor 124 may perform logical operations defined in the firmware loaded on the working memory 125 to control the overall operation of the controller 120. The processor 124 may store results of performing the logical operations defined in the firmware in the working memory 125. The processor 124 may control the controller 120 to generate a command or a signal according to the results of performing the logical operations defined in the firmware. When a part of firmware, in which a logical operation to be performed is defined, is not loaded on the working memory 125, the processor 124 may generate an event (e.g., interrupt) for loading the part of the firmware onto the working memory 125.

The processor 124 may load metadata that is required to drive the firmware from the memory device 110. The metadata is data for managing the memory device 110 and may include management information on the user data stored in the memory device 110.

The firmware may be updated while the data storage device 100 is manufactured or the data storage device 100 is executed. The controller 120 may download new firmware from the outside of the data storage device 100 and update existing firmware with the new firmware.

The working memory 125 may store firmware, program codes, commands, or data required to drive the controller 120. The working memory 125 is, for example, a volatile memory and may include one or more of static RAM (SRAM), dynamic RAM (DRAM), synchronous DRAM (SDRAM), and the like.

The ECC circuit 126 may detect error bits of target data using an error correction code, and correct the detected error bits. Here, the target data may be, for example, data stored in the working memory 125 or data read from the memory device 110.

The ECC circuit 126 may be implemented to decode data using an error correction code. The ECC circuit 126 may be implemented using various code decoders. For example, a decoder that performs unsystematic code decoding or a decoder that performs systematic code decoding may be used.

A bus 127 may provide a channel between the components 121, 122, 124, 125, and 126 of the controller 120. The bus 127 may include, for example, a control bus for transmitting various control signals, commands, and the like, a data bus for transmitting various data, and the like.

Some of the components 121, 122, 124, 125, and 126 of the controller 120 described above may be omitted, or some components among the components 121, 122, 124, 125, and 126 of the controller 120 described above may be integrated into one. In some cases, one or more other components may be added, in addition to the components of the controller 120 described above.

Currently, the data storage device has a structure in which each of a plurality of flash translation layers (FTLs) manages a different memory area. Here, each memory area is a structure configured of at least one die and is separated physically or logically. The actual size of a memory area may be greater than the size of the memory area recognized by an external device so that operations of a data storage device may be performed smoothly even when bad blocks are generated. For example, the memory area may be designed to have a spare region of 5%. When the size of the memory area recognized by an external device is 1 GB, that is, when the size of the memory area according to the logical address assigned to the memory area by the external device is 1 GB, the size of the actual memory area may be 1.05 GB.

Therefore, even when a bad block is generated in a memory area and thus the memory block may not be used, the FTL that manages the memory area processes so that data may not be stored in the bad block to continue the operation. Generally, the lifespan of a data storage device may be determined by a specific ratio of bad blocks. For example, when the size of bad blocks in a data storage device grows to be more than 2.5% of the size of the memory area, the life of the data storage device may be considered as being completed. Interpreting in another way, when the size of the spare region in a data storage device is less than 2.5% of the size of the memory area, the life of the data storage device may be considered as being completed.

When the data storage device includes a plurality of memory areas completely separated from each other physically and managed by a plurality of FTLs, and the size of bad blocks is equal to or higher than a preset ratio even in a single memory area among the plurality of memory areas, it is considered that the life of the data storage device is completed, rather than considering that only the life of the memory area is completed. This is due to a problem that may occur when an external device writes on the memory area. Therefore, even when only one memory area among a plurality of memory areas reaches a preset specific ratio although a preset specific ratio is not reached from the aspect of the whole data storage device, there occurs a problem of inefficiency that considers the life of the data storage device itself to be completed.

In addition, although the lifespan of the data storage device is extended by sharing bad block information between the FTLs, and this has the effect of extending the lifespan of the data storage device itself, a phenomenon of concentrating commands on a specific FTL occurs, and transmission of data between the separated FTLs is required, which has not been necessary in the past, and according to a method of dealing with the phenomenon, this may act as a factor that hinders performance and consistency.

Hereinafter, a method of efficiently managing memory areas based on defect information (e.g., bad block information) of the memory areas will be described below.

The method described below may be a management method for maintaining the spare region of each memory area at a predetermined ratio or size or higher.

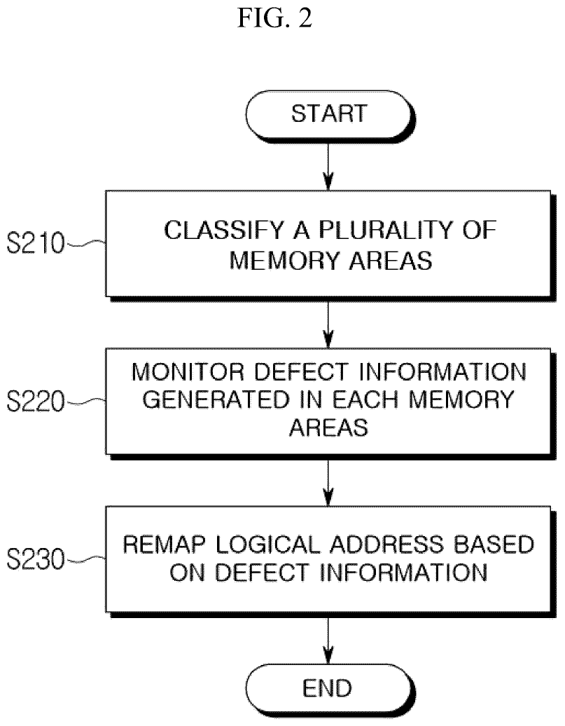

FIG. 2 is a flowchart illustrating an operation method of a data storage device according to an embodiment of the present disclosure. Hereinafter, the memory device 110 may include a plurality of memory areas physically separated and distinguished from each other by different physical addresses. Each memory area may be mapped to a logical address area recognized by an external device. According to an embodiment, the logical address may be expressed as a logical page number (LPN).

The controller 120 may classify (or determine) a plurality of memory areas as a plurality of storage areas (S210). That is, the controller 120 does not manage the entire memory area as one item, may classify the entire memory area as a plurality of storage areas and may separately manage the plurality of storage areas. According to an embodiment, at least one memory area physically separated with other memory areas may be regarded as a storage area, and accordingly, a storage area may be mapped to a logical address area recognized by an external device.

The controller 120 may monitor defect information generated in the memory areas respectively corresponding to the plurality of storage areas (S220). Accordingly, the controller 120 may confirm in which memory area the defect information is generated. The defect information may include a bad block count value.

The controller 120 may change the logical address mapped to each of the plurality of storage areas by remapping the logical address to each of the plurality of storage areas based on the defect information (S230). This may be the same as changing the logical address mapped to each memory area.

The operation method of the data storage device 100 shown in FIG. 2 may be performed by the processor 124 by driving firmware. In the following embodiment, a data storage device that remaps logical addresses using a bad block count value, which is an example of defect information of each flash translation layer (FTL), and an operation method thereof will be described. Hereinafter, a logical page number (LPN) will be described as an example of the logical address.

Hereinafter, the controller 120 may include a host interface layer (hereinafter, referred to as ‘HIL’) and a flash translation layer (hereinafter, referred to as ‘FTL’). In addition, the HIL and FTL may be firmware driven by the processor 124. The processor 124 that drives the HIL and FTL may be implemented as a single processor or may be implemented as a plurality of processors according to another embodiment.

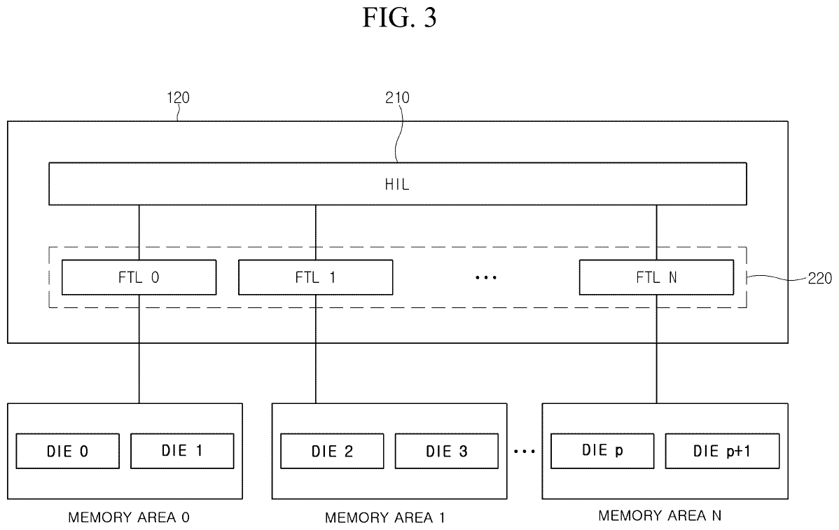

FIG. 3 is a block diagram for describing a controller according to an embodiment of the present disclosure.

As shown in FIG. 3, the controller 120 may include a HIL 210 and a plurality of FTLs 220. The HIL 210 may transmit commands received from the external device 150 to the plurality of FTLs 220. The plurality of FTLs 220 may classify (or determine) a plurality of memory areas as a plurality of storage areas and separately manage the plurality of memory areas. For example, FTL 0 may manage memory area 0 as storage area 0, FTL 1 may manage memory area 1 as storage area 1, and FTL N may manage memory area N as storage area N. Each memory area may include at least one die.

According to an embodiment, the HIL 210 may acquire a logical address included in a command transmitted from an external device and transmit the command to an FTL that manages a storage area to which the logical address is mapped.

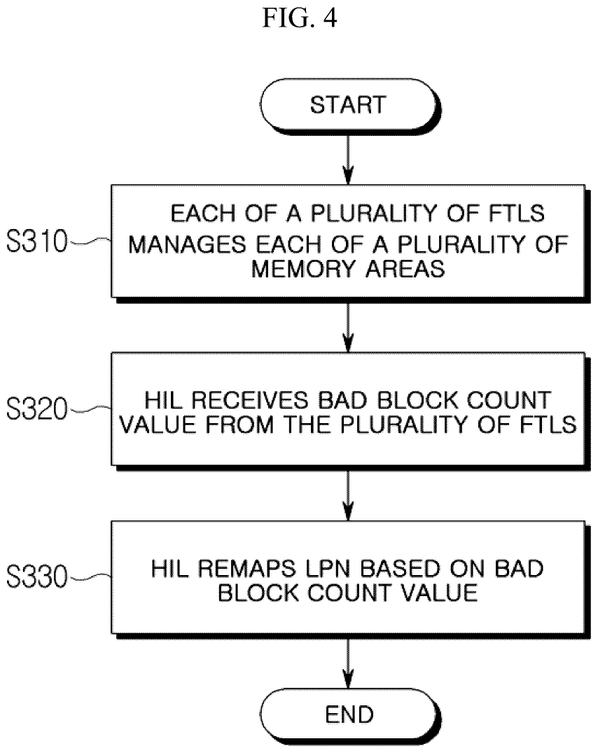

FIG. 4 is a flowchart for managing bad blocks by a controller according to an embodiment of the present disclosure.

Each of the plurality of FTLs 220 may manage one memory area among the plurality of memory areas (S310). In addition, each of the plurality of FTLs 220 may monitor a bad block count value generated in the memory area that it manages.

Each of the plurality of FTLs 220 may maintain a bad block count value. Each of the plurality of FTLs 220 may update the bad block count value when a bad block is generated in the memory area that it manages. The bad block count value is based on the number of bad memory blocks existing in a corresponding memory area, and may be expressed as the number of bad blocks, the ratio of bad blocks in the memory area, or the like.

The HIL 210 may receive a bad block count value from each of the plurality of FTLs 220 (S320). Receiving the bad block count value may be performed every time of booting or whenever a bad block is generated.

The HIL 210 may remap a logical address (or LPN) based on the bad block count value received from each of the plurality of FTLs 220 (S330). That is, the HIL 210 may perform an operation of changing the logical address mapped to each of the plurality of storage areas by respectively remapping the logical addresses to the plurality of storage areas based on the bad block count value. The remapping operation may be performed through release and addition of a logical address mapped to a target storage area. Alternatively, the remapping operation may be newly setting a logical address mapped to a target storage area. When a storage area corresponding to a logical address is changed from a first storage area to a second storage area due to remapping of the logical address, it needs to move data of the logical address stored in the first storage area to the second storage area.

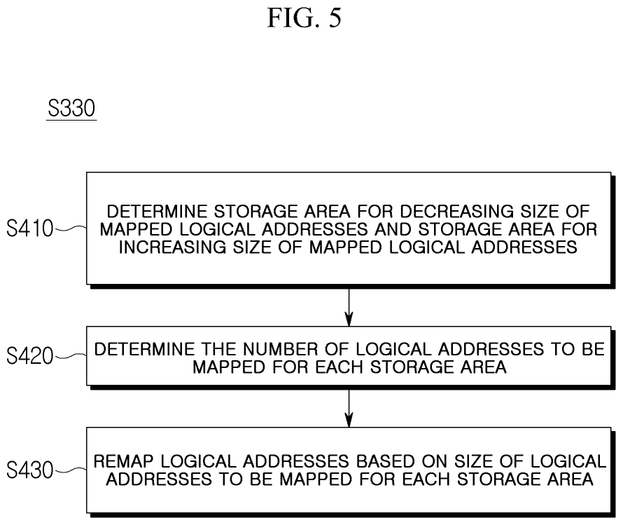

FIG. 5 is a flowchart illustrating in detail the operation S330 shown in FIG. 4.

The HIL 210 may determine a storage area for decreasing the number of mapped logical addresses and a storage area for increasing the number of mapped logical addresses by comparing the bad block count value received from each of the plurality of FTLs 220 with a reference value of bad block count (hereinafter, referred to as a ‘reference value’) (S410). Details thereof will be described below.

When a storage area for decreasing the number of mapped logical addresses and a storage area for increasing the number of mapped logical addresses are determined, the HIL 210 may determine the number of logical addresses to be mapped for each storage area (S420) and remap the logical addresses based on the determined number of logical addresses to be mapped for each storage area (S430).

The method of the HIL 210 for remapping logical addresses to a storage area may include a sequential method and a release allocation method.

According to an embodiment, the sequential method may be a method of remapping logical addresses so that the logical addresses mapped to each storage area may sequentially increase. The HIL 210 may reset and remap the logical addresses to be mapped to each of the plurality of storage areas based on the determined number of logical addresses to be mapped for each storage area so that the logical addresses mapped to each storage area may increase sequentially. At this point, when a target storage area for mapping the logical addresses is changed, movement of data may be accompanied. For example, when logical address A is mapped to a first storage area and then mapped to a second storage area through remapping, data corresponding to logical address A stored in the first storage area needs to be moved to the second storage area.

According to another embodiment, the release allocation method may be a method of releasing some logical addresses from a decrease target storage area and allocating the released logical addresses to an increase target storage area. The HIL 210 may perform logical address remapping in a method of releasing some of the logical addresses mapped to a decrease target storage area and mapping the released logical addresses to an increase target storage area. The HIL 21 may release mapping of logical addresses as many times as the number of logical addresses to be decreased among previously mapped logical addresses for a decrease target storage area, and map the logical addresses unmapped from the decrease target storage area to an increase target storage area. At this point, although the HIL 210 may arbitrarily select logical addresses to be released from the decrease target storage area, the HIL 210 may select logical addresses where data is not stored in the decrease target storage area as logical addresses for releasing mapping in order to minimize movement of data described above.

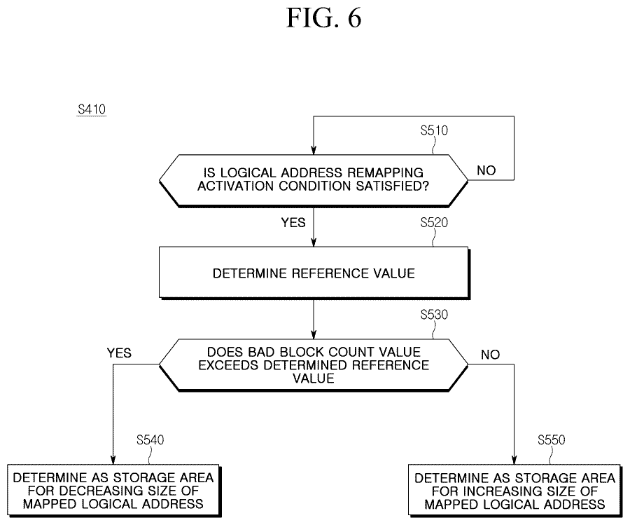

FIG. 6 is a flowchart illustrating in detail the operation S410 shown in FIG. 5.

The HIL 210 may determine whether a logical address remapping activation condition is satisfied (S510). The HIL 210 determines whether a logical address remapping activation condition is satisfied to perform remapping only when it is determined that logical address remapping is necessary, since operating without logical address remapping may be more efficient, for example, when the bad block count value of all storage areas is small, i.e., when the ratio of spare regions of all memory areas is greater than a preset value.

According to an embodiment, the HIL 210 may determine that logical address remapping is activated unconditionally. This condition may be the same as when the HIL 210 directly executes operation S520 without performing operation S510.

According to another embodiment, the HIL 210 may perform logical address remapping at regular time intervals. The HIL 210 may determine that the activation condition is satisfied when a predetermined time has elapsed after performing logical address remapping.

According to another embodiment, the HIL 210 may acquire a bad block count value for each storage area and determine whether the bad block count value for at least one storage area exceeds a preset activation value. Here, the activation value is a reference for activating logical address remapping for each storage area, and may be, for example, a bad block count value that makes the size of bad blocks to be 2% of the size of the memory area. This activates logical address remapping before the life of a memory area is completed since it is conventionally determined that the life of a memory area is completed when the size of bad blocks reaches 2.5% of the memory area size.

When the logical address remapping activation condition is satisfied, the HIL 210 may determine a reference value (S520). According to an embodiment, the HIL 210 may determine an average of the bad block count value of each storage region as the reference value. According to another embodiment, the HIL 210 may determine a value to be set arbitrarily as the reference value.

The HIL 210 may determine by comparison whether the bad block count value of each storage area exceeds the reference value (S530). As a result of the comparison, the HIL 210 may determine a storage area where the bad block count value exceeds the reference value as a storage area for decreasing the number of mapped logical addresses (S540), and determine a storage area where the bad block count value does not exceed the reference value as a storage area for increasing the number of mapped logical addresses (S550).

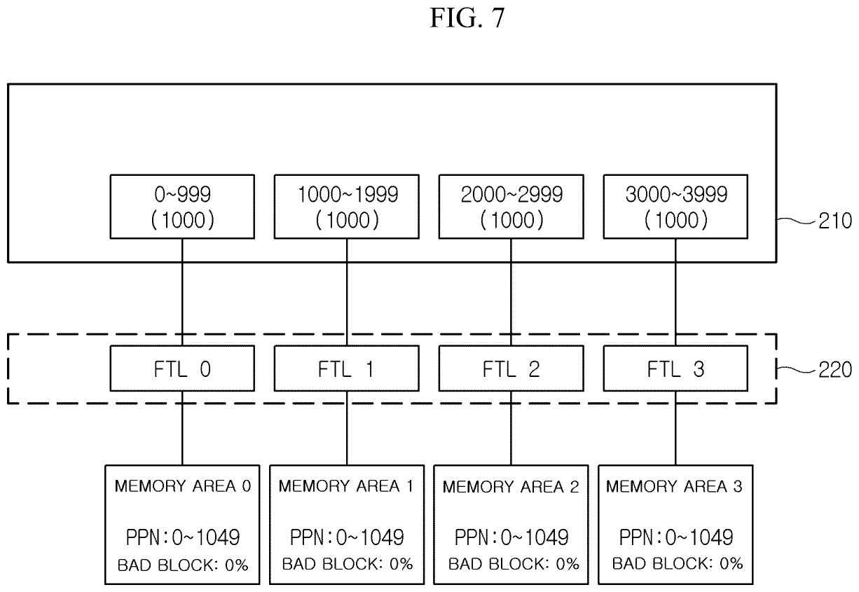

FIGS. 7 to 9 are views for describing the operation of the controller shown in FIGS. 5 and 6 according to various embodiments of the present disclosure.

FIG. 7 may be a view showing the initial state when the data storage device 100 is used after being manufactured as a product.

The external device 150 may recognize the data storage device 100 as a specific logical address area. In the example of FIG. 7, the external device 150 may recognize the data storage device 100 as logical addresses 0 to 3,999. Accordingly, the external device 150 may transmit a command including a logical address between logical addresses 0 and 3,999 to the data storage device 100 to store data in the data storage device 100 or to read data from the data storage device 100.

The data storage device 100 may have a plurality of memory areas separated from each other, and map logical addresses for each memory area. In the example of FIG. 7, logical addresses 0 to 999 may be mapped to memory area 0, logical addresses 1,000 to 1,999 may be mapped to memory area 1, logical addresses 2,000 to 2,999 may be mapped to memory area 2, and logical addresses 3,000 to 3,999 may be mapped to memory area 3. This mapping operation may be performed by the HIL 210.

When a command is received from the external device 150, the HIL 210 may acquire a logical address included in the command and transmit the command to an FTL 220 that manages a memory area to which the logical address is mapped. The FTL 220 may store data in the memory area or read data from the memory area based on the received command. At this point, the FTL 220 may map a logical address and a physical page number (PPN) of the memory area to store data in the physical address or read data from the physical address. Here, one physical address may represent one memory block, but the embodiments are not limited thereto.

As shown in FIG. 7, each memory area may have more physical addresses than the number of mapped logical addresses. When the memory area is used for a long time and reading and storing operations are repeated, physical characteristics of memory cells may deteriorate, and bad blocks that cannot store data any longer may be generated. Each memory area may have more physical addresses than the number of mapped logical addresses to operate as a data storage device although bad blocks are generated to some extent.

In the example of FIG. 7, each memory area has a spare region of about 5%. That is, each memory area has a memory area corresponding to 1,050 physical addresses, so that even when data of 1,000 mapped logical addresses is stored, there is a spare region of 5% (50 logical addresses).

When a specific physical address is determined as a bad block that cannot be used any longer, the physical address is not used any longer, and a physical address of the spare region may be used. This is possible as the FTL 220 changes the physical address mapped to the logical address.

In addition, a predetermined spare region is needed to perform background operations such as garbage collection (GC), wear leveling (WL), and read reclaim (RR) of the FTL 220.

In the case of the example shown in FIG. 7, it may be determined that the logical address remapping activation condition of operation S510 is not satisfied. Since each memory area has a sufficient spare region and there are no bad blocks, it may be determined that logical address remapping is not necessary.

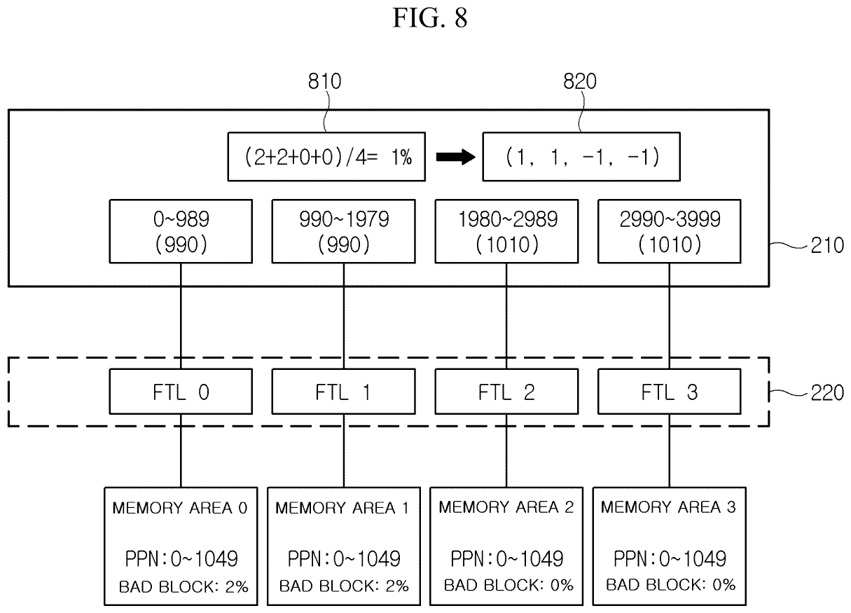

FIG. 8 shows an example in which bad blocks of 2% (20 physical addresses) are generated in memory area 0 and memory area 1.

When bad blocks of 2% or more are generated in at least one memory area as shown in the example of FIG. 8, the logical address remapping activation condition of operation S510 is satisfied, and logical address remapping may be activated.

In determining the reference value (S520), the HIL 210 of the controller 120 may set 2% (20 physical addresses), which is the same as the activation condition, as the reference value according to an embodiment, or set an average of the bad block count of the entire memory area as the reference value according to another embodiment.

In the example of FIG. 8, an average of the bad block count of the entire memory area is set as the reference value (810).

The reference value (R) may be calculated as shown in Equation 1.

$$R = \frac{{\sum }_{n = 0}^{x - 1} {BB}_{n}}{x} \qquad [ Equation 1 ]$$

Here, x denotes the number of memory areas provided in the data storage device 100 to operate independently from each other, and BBₙ denotes the count value of bad blocks in the n-th memory area.

Referring to the example of FIG. 8, the reference value (R) may be 1%.

The HIL 210 may determine a reference value, and determine a memory area (storage area) for decreasing the number of mapped logical addresses and a memory area for increasing the number of mapped logical addresses based on the reference value.

When a value obtained by subtracting the reference value from the bad block count value of each memory area is greater than 0, the HIL 210 may determine the memory area as a memory area for decreasing the number (size) of mapped logical addresses, and when the obtained value is less than 0, the HIL 210 may determine the memory area as a memory area for increasing the number (size) of mapped logical addresses.

In the example of FIG. 8, the values obtained by subtracting the reference value from the bad block count value of each memory area are shown as (1, 1, −1, −1) 820, and from the obtained values, the HIL 210 may determine memory area 0 and memory area 1 as memory areas for decreasing the number of mapped logical addresses, and determine memory area 2 and memory area 3 as memory areas for increasing the number of mapped logical addresses.

The HIL 210 may determine the number of logical addresses to be mapped for each memory area (storage area). This may be the same as determining the number (size) of logical addresses to be decreased or the number (size) of logical addresses to be increased for each memory area.

The HIL 210 may determine the number of logical addresses to be decreased or the number of logical addresses to be increased for each memory area based on (1, 1, −1, −1) 820, which are values obtained by subtracting the reference value from the bad block count value of each memory area described above. In the example of FIG. 8, since 1% may correspond to 10 logical addresses, the number of logical addresses to be decreased in memory area 0 and memory area 1 is 10, and the number of logical addresses to be increased in memory area 2 and memory area 3 is 10. Accordingly, 990 logical addresses may be remapped in memory areas 0 and 1, and 1,010 logical addresses may be remapped in memory areas 2 and 3.

The example of FIG. 8 shows remapping according to the sequential method. The HIL 210 may remap 990 logical addresses of logical addresses 0 to 989 in memory area 0, remap 990 logical addresses of logical addresses 990 to 1,979 in memory area 1, remap 1,010 logical addresses of logical addresses 1,980 to 2,989 in memory area 2, and remap 1,010 logical addresses of logical addresses 2,990 to 3,999 in memory area 3 so that the mapped logical addresses may increase sequentially.

At this point, when data corresponding to logical addresses of logical addresses 990 to 999 are stored in memory area 0, the HIL 210 needs to move the data to memory area 1. In addition, when data corresponding to logical addresses of logical addresses 1,980 to 1,999 are stored in memory area 1, the HIL 210 needs to move the data to memory area 2. In addition, when data corresponding to logical addresses of logical addresses 2,990 to 2,999 are stored in memory area 2, the HIL 210 needs to move the data to memory area 3.

Although not shown in FIG. 8, when remapping is performed according to the release allocation method, the HIL 210 may release mapping of logical addresses (e.g., logical addresses 0 to 9), of which data is not stored in memory area 0, among the logical addresses mapped to memory area 0, and perform a remapping operation of additionally mapping corresponding logical addresses to memory area 2. Thereafter, when a command for storing data in logical addresses 0 to 9 is received, the HIL 210 may transmit the command to FTL 2 so that data corresponding to the logical addresses may be stored in memory area 2. In a similar manner, the HIL 210 may release mapping of logical addresses (e.g., logical addresses 1,100 to 1,109), of which data is not stored in memory area 1, among the logical addresses mapped to memory area 1, and perform a remapping operation of additionally mapping the corresponding logical addresses to memory area 3.

When logical address remapping like this is performed, the size of the spare region provided in each memory area may be equally 4% (data size corresponding to 40 logical addresses). For example, memory area 0 may have 1,030 available physical addresses out of 1,050 physical addresses, excluding 20 bad blocks, and as the number of logical addresses mapped thereto is 990, it may have a spare region corresponding to 40 physical addresses. In addition, memory area 4 may use all 1,050 physical addresses, and as the number of logical addresses mapped thereto is 1,010, it may have a spare region corresponding to 40 physical addresses.

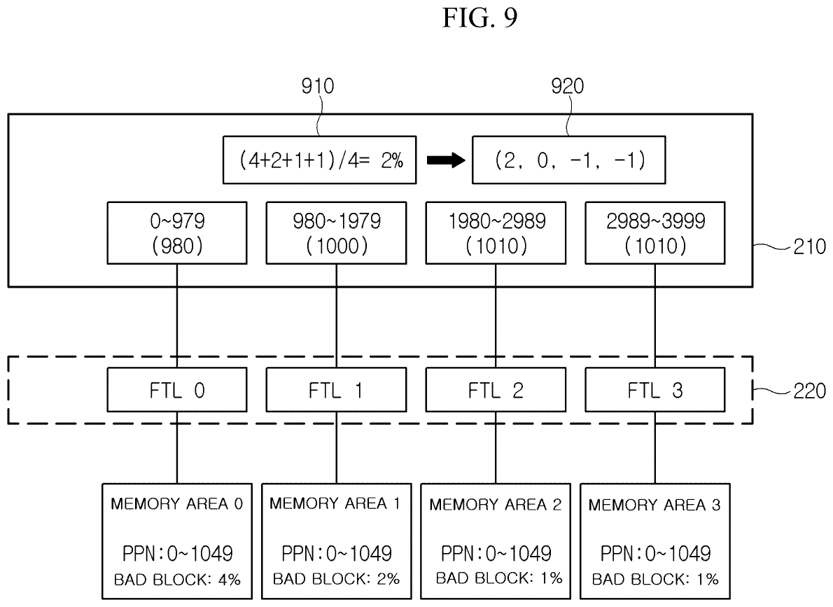

FIG. 9 shows an example in which 4% (40 physical addresses) of bad blocks are generated in memory area 0, 2% (20 physical addresses) of bad blocks are generated in memory area 1, and 1% (10 physical addresses) of bad blocks are generated in memory area 2 and memory area 3. When bad blocks of 2% or more are generated in at least one memory area as shown in the example of FIG. 9, the logical address remapping activation condition of operation S510 is satisfied, and logical address remapping may be activated.

In determining the reference value (S520), the HIL 210 of the controller 120 may set an average of the bad block count 910 of the entire memory area as the reference value as shown in FIG. 9.

The reference value (R) may be calculated as shown in Equation 1 used in the example of FIG. 8.

Referring to the example of FIG. 9, the reference value (R) may be 2%.

The HIL 210 may determine a reference value, and determine a memory area (storage area) for decreasing the number of mapped logical addresses and a memory area for increasing the number of mapped logical addresses based on the reference value.

When a value obtained by subtracting the reference value from the bad block count value of each memory area is greater than 0, the HIL 210 may determine the memory area as a memory area for decreasing the number of mapped logical addresses, and when the obtained value is less than 0, the HIL 210 may determine the memory area as a memory area for increasing the number of mapped logical addresses.

In the example of FIG. 9, the values obtained by subtracting the reference value from the bad block count value of each memory area are shown as (2, 0, −1, −1) 920, and from the obtained values, the HIL 210 may determine memory area 0 and memory area 1 as memory areas for decreasing the number of mapped logical addresses, and determine memory area 2 and memory area 3 as memory areas for increasing the number of mapped logical addresses.

The HIL 210 may determine the number of logical addresses to be mapped for each memory area (storage area). This may be the same as determining the number of logical addresses to be decreased or the number of logical addresses to be increased for each memory area.

The HIL 210 may determine the number of logical addresses to be decreased in memory area 0 as 20 and the number of logical addresses to be increased in memory area 2 and memory area 3 as 10 based on (2, 0, −1, −1) 920, which are values obtained by subtracting the reference value from the bad block count value of each memory area described above. In the example of FIG. 9, since 1% may correspond to 10 logical addresses, the number of logical addresses to be decreased in memory area 0 is 20, and the number of logical addresses to be increased in memory area 2 and memory area 3 is 10. Accordingly, 980 logical addresses may be remapped in memory area 0, and 1,010 logical addresses may be remapped in memory area 2 and memory area 3. In memory area 1, 1,000 logical addresses may be mapped in the same manner.

The example of FIG. 9 shows remapping according to the sequential method. The HIL 210 may remap 980 logical addresses of logical addresses 0 to 979 in memory area 0, remap 1,000 logical addresses of logical addresses 980 to 1,979 in memory area 1, remap 1,010 logical addresses of logical addresses 1,980 to 2,989 in memory area 2, and remap 1,010 logical addresses of logical addresses 2,990 to 3,999 in memory area 3 so that the mapped logical addresses may increase sequentially.

At this point, when data corresponding to logical addresses of logical address 980 to 999 are stored in memory area 0, the HIL 210 needs to move the data to memory area 1. In addition, when data corresponding to logical addresses of logical addresses 1,980 to 1,999 are stored in memory area 1, the HIL 210 needs to move the data to memory area 2. In addition, when data corresponding to logical addresses of logical addresses 2,990 to 2,999 are stored in memory area 2, the HIL 210 needs to move the data to memory area 3.

When logical address remapping like this is performed, the size of the spare region provided in each memory area may be equally 3% (data size corresponding to 30 logical addresses). For example, memory area 0 may have 1,010 available physical addresses out of 1,050 physical addresses, excluding 40 bad blocks corresponding to 4%, and as the number of logical addresses mapped thereto is 980, it may have a spare region corresponding to 30 physical addresses. In addition, memory area 4 may have 1,040 available physical addresses out of 1,050 physical addresses, excluding 10 bad blocks corresponding to 1%, and as the number of logical addresses mapped thereto is 1,010, it may have a spare region corresponding to 30 physical addresses.

According to the embodiments of the present disclosure, the lifespan of a data storage device can be extended by adjusting the size or ratio of the spare storage region of each of a plurality of memory areas.

According to the embodiments of the present disclosure, as the ratio of the spare storage region of all memory areas in the memory device is maintained to be equal to or higher than a predetermined size or ratio in a method of changing the number of logical addresses mapped to a plurality of memory areas, performance and consistency of the memory device can be maintained without a complicated map management and calculation process.

The above description merely illustrates the technical spirit of the present disclosure as an example, and those skilled in the art may make various changes and modifications without departing from the essential characteristics of the present disclosure. In addition, since the embodiments disclosed in the present disclosure are intended not to limit the technical spirit of the present disclosure, but to describe it, the scope of the technical spirit of the present disclosure is not limited by the embodiments. The scope of protection of the present disclosure should be interpreted in accordance with the claims provided below, and all technical spirits within the scope equivalent thereto should be interpreted as being included in the scope of rights of the present disclosure.

According to the embodiments of the present disclosure, the lifespan of a data storage device can be extended by adjusting the size or ratio of the spare storage region of each of a plurality of memory areas.

According to embodiments of the present disclosure, as the ratio of the spare storage region of all memory areas in the memory device is maintained to be equal to or higher than a predetermined size or ratio in a method of changing the number of logical addresses mapped to a plurality of memory areas, performance and consistency of the memory device can be maintained without a complicated map management and calculation process.

While embodiments of the present disclosure have been described with reference to the attached drawings, it would be understood by those of ordinary skill in the art that the technical configuration of the present invention may be implemented in other detailed forms without changing the technical spirit or the essential features of the present invention. Thus, it should be noted that the above-described embodiments are provided as examples and should not be interpreted as limiting. Moreover, the scope of the present invention should be defined by the following claims rather than the detailed description provided above. Furthermore, the meanings and scope of the claims and all changes or modified forms derived from their equivalents should be construed as falling within the scope of the present invention, and the disclosed embodiments may be combined to form additional embodiments.

What is claimed is:

1. A data storage device comprising:
a memory device including a plurality of memory areas; and
a controller configured to
classify the plurality of memory areas as a plurality of storage areas,
manage the plurality of storage areas by mapping logical addresses externally received to each of the plurality of storage areas,
monitor defect information generated in a memory area corresponding to each of the plurality of storage areas, and
remap the logical addresses for each of the plurality of storage areas based on the defect information.

2. The data storage device according to claim 1,
wherein the controller is further configured to:
determine, based on defect information in each of the plurality of storage areas, a decrease target storage area for decreasing a number of mapped logical addresses and an increase target storage area for increasing a number of mapped logical addresses;
determine a number of logical addresses to be mapped to each of the plurality of storage areas based on the determination; and
remap the logical addresses to each of the plurality of storage areas based on the number of logical addresses to be mapped, which is determined for each of the plurality of storage areas.

3. The data storage device according to claim 2,
wherein the controller is further configured to:
determine a reference value,
compare a defect information monitoring value of each of the plurality of storage areas with the reference value,
determine a storage area, of which the defect information monitoring value is greater than the reference value, as the decrease target storage area, and
determine a storage area, of which the defect information monitoring value is less than the reference value, as the increase target storage area.

4. The data storage device according to claim 3,
wherein the controller is further configured to determine an average of the defect information monitoring value of each of the plurality of storage areas as the reference value.

5. The data storage device according to claim 3,
wherein the controller is further configured to:
determine a number of logical addresses to be decreased for each storage area of the decrease target storage area in proportion to a value obtained by subtracting the reference value from the defect information monitoring value of each storage area, and
determine a number of logical addresses to be increased for each storage area of the increase target storage area in proportion to a value obtained by subtracting the defect information monitoring value of each storage area from the reference value.

6. The data storage device according to claim 3,
wherein the controller is further configured to:
determine a number of logical addresses to be decreased for each storage area of the decrease target storage area in proportion to a value obtained by subtracting the reference value from the defect information monitoring value of each storage area,
acquire a total number of logical addresses to be decreased by adding up the number of logical addresses to be decreased for each storage area of the decrease target storage area,
acquire a number of storage areas corresponding to the increase target storage area, and
equally determine a number of logical addresses to be increased for each storage area of the increase target storage area based on a value obtained by dividing the total number of logical addresses to be decreased by the number of storage areas corresponding to the increase target storage area.

7. The data storage device according to claim 5,
wherein the controller is further configured to:
remap the logical addresses to each of the plurality of storage areas based on the number of logical addresses to be decreased or the number of logical addresses to be increased, which is determined for each storage area; and
remap the logical addresses mapped to each storage area to increase sequentially.

8. The data storage device according to claim 5,
wherein the controller is configured to:
remap the logical addresses to each of the plurality of storage areas based on the number of logical addresses to be decreased or the number of logical addresses to be increased, which is determined for each storage area;
release mapping of logical addresses for as many as the number of logical addresses to be decreased among previously mapped logical addresses for the decrease target storage area; and
map logical addresses unmapped from the decrease target storage area for an increase target storage area.

9. The data storage device according to claim 1,
wherein the controller is configured to:
determine a logical address remapping activation condition; and
remap the logical addresses to each of the plurality of storage areas only when the logical address remapping activation condition is satisfied.

10. The data storage device according to claim 1,
wherein the defect information includes a bad block count value.

11. An operation method of a data storage device including a memory device and a controller, the operation method comprising:
classifying, by the controller, a plurality of memory areas provided in the memory device into a plurality of storage areas;
managing, by the controller, the plurality of storage areas by mapping logical addresses externally received to each of the plurality of storage areas;
monitoring, by the controller, defect information generated in a memory area corresponding to each of the plurality of storage areas; and
remapping, by the controller, the logical addresses for each of the plurality of storage areas based on the defect information.

12. The operation method according to claim 11,
wherein remapping the logical addresses for each of the plurality of storage areas comprises:
determining, based on defect information in each of the plurality of storage areas, a decrease target storage area for decreasing a number of mapped logical addresses and an increase target storage area for increasing a number of mapped logical addresses;
determining a number of logical addresses to be mapped to each of the plurality of storage areas based on the determination; and
remapping the logical addresses to each of the plurality of storage areas based on the number of logical addresses to be mapped to each of the plurality of determined storage areas.

13. The operation method according to claim 12,
wherein determining the decrease target storage area comprises:
determining a reference value;
comparing a defect information monitoring value of each of the plurality of storage areas with the reference value;
determining a storage area, of which the defect information monitoring value is greater than the reference value, as the decrease target storage area, and
determining a storage area, of which the defect information monitoring value is less than the reference value, as the increase target storage area.

14. The operation method according to claim 13,
wherein determining the reference value comprises determining an average of the defect information monitoring value of each of the plurality of storage areas as the reference value.

15. The operation method according to claim 13,
wherein determining the number of logical addresses to be mapped to each of the plurality of storage areas comprises:
determining a number of logical addresses to be decreased for each storage area of the decrease target storage area in proportion to a value obtained by subtracting the reference value from the defect information monitoring value of each storage area; and
determining a number of logical addresses to be increased for each storage area of the increase target storage area in proportion to a value obtained by subtracting the defect information monitoring value of each storage area from the reference value.

16. The operation method according to claim 13,
wherein determining the number of logical addresses to be mapped to each of the plurality of storage areas comprises:
determining the number of logical addresses to be decreased for each storage area of the decrease target storage area in proportion to a value obtained by subtracting the reference value from the defect information monitoring value of the storage area;
acquiring a total number of logical addresses to be decreased by adding up the number of logical addresses to be decreased for each storage area of the decrease target storage area;
acquiring a number of storage areas corresponding to the increase target storage area; and
equally determining a number of logical addresses to be increased for each storage area of the increase target storage area based on a value obtained by dividing a total number of logical addresses to be decreased by the number of storage areas corresponding to the increase target storage area.

17. The operation method according to claim 15,
wherein remapping the logical addresses to each of the plurality of storage areas comprises:
remapping the logical addresses to each of the plurality of storage areas based on the number of logical addresses to be decreased or the number of logical addresses to be increased, which is determined for each storage area; and
remapping the logical addresses mapped to each storage area to increase sequentially.

18. The operation method according to claim 15,
wherein remapping the logical address to each of the plurality of storage areas comprises:
remapping the logical addresses to each of the plurality of storage areas based on the number of logical addresses to be decreased or the number of logical addresses to be increased, which is determined for each storage area;
releasing mapping of logical addresses for as many as the number of logical addresses to be decreased among previously mapped logical addresses for the decrease target storage area; and
mapping logical addresses unmapped from the decrease target storage area for an increase target storage area.

19. The operation method according to claim 11, further comprising:
determining a logical address remapping activation condition and
remapping the logical addresses to each of the plurality of storage areas only when the logical address remapping activation condition is satisfied.

20. The operation method according to claim 11,
wherein the defect information includes a bad block count value.
